(19) United States
(12) Patent Application Publication
(10) Pub. No.: US 2022/0246659 A1
(43) Pub. Date: Aug. 4, 2022

(54) IMAGING DEVICE AND IMAGING APPARATUS

(71) Applicant: SONY SEMICONDUCTOR SOLUTIONS CORPORATION, KANAGAWA (JP)

(72) Inventor: KOUICHI INOUE, KUMAMOTO (JP)

(21) Appl. No.: 17/623,790

(22) PCT Filed: Jun. 12, 2020
(86) PCT No.: PCT/JP2020/023167

§ 371 Date: Dec. 29, 2021

(30) Foreign Application Priority Data
Jul. 11, 2019 (JP) 2019-129025
Jun. 4, 2020 (JP) 2020-097947

(51) Int. Cl. H01L 27/146

(52) U.S. Cl. CPC H01L 27/14623; H01L 27/14621; H01L 27/14629; H01L 27/14627; H01L 27/14625

(57) ABSTRACT

Reflected light from a back-illuminated imaging device is to be reduced. The imaging device includes an on-chip lens, a photoelectric conversion unit, and an absorption film. The on-chip lens included in the imaging device condenses incident light. The photoelectric conversion unit included in the imaging device is formed in a semiconductor substrate, and performs photoelectric conversion on the condensed incident light. The absorption film included in the imaging device is disposed adjacent to the semiconductor substrate, has an opening of substantially the same size as the condensing size of the condensed incident light, and absorbs reflected light of the incident light.

### TECHNICAL FIELD

The present disclosure relates to an imaging device and an imaging apparatus. More particularly, the present disclosure relates to an imaging device irradiated with incident light from the back surface of a semiconductor substrate, and an imaging apparatus using the imaging device.

### BACKGROUND ART

Imaging devices in which incident light is emitted onto the back surface side of a semiconductor substrate have been conventionally used. Photoelectric conversion units such as photodiodes that photoelectrically convert incident light are formed in the semiconductor substrate. As incident light is emitted onto the photoelectric conversion units without passing through the wiring region formed on the front surface of the semiconductor substrate, sensitivity can be improved.

As such an imaging device, for example, an imaging device in which a photodiode or the like is formed in a silicon layer of a silicon-on-insulator (SOI) substrate formed by sequentially stacking an intermediate layer and the silicon layer on a silicon substrate is used (see Patent Document 1, for example). In this imaging device, a wiring portion (wiring region) is formed on the front surface of the silicon layer in which a light receiving sensor unit such as a photodiode is formed. After a support substrate is bonded to the wiring region, the silicon substrate and the intermediate layer are removed. A silicon thin film having a thickness of 10 μm or smaller can be used as the silicon layer. As the step of thinning the semiconductor substrate by grinding or the like is unnecessary, silicon layers having a stable thickness can be manufactured with a high yield.

### CITATION LIST

### Patent Document

### Patent Document 1: Japanese Patent Application Laid-Open No. 2007-335905

### SUMMARY OF THE INVENTION

### Problems to be Solved by the Invention

With the conventional technique described above, there is the problem of a large amount of reflected light from an imaging device. Since a thin silicon layer is used as the semiconductor substrate in which a photodiode or the like is formed, incident light that has not been absorbed by the semiconductor substrate reaches the wiring region and is reflected, resulting in a large amount of reflected light. When this reflected light enters the imaging device again, flare or the like occurs, and image quality is degraded.

The present disclosure is made in view of the above problems, and aims to reduce reflected light from a back-illuminated imaging device.

### Solutions to Problems

The present disclosure is made to solve the above problems, and a first aspect thereof is an imaging device that includes: an on-chip lens that condenses incident light; a photoelectric conversion unit that is formed in a semiconductor substrate and performs photoelectric conversion on the condensed incident light; and an absorption film that is disposed adjacent to the semiconductor substrate, has an opening of substantially the same size as the condensing size of the condensed incident light, and absorbs reflected light of the incident light.

Also, in the first aspect, the imaging device may further include a reflective film that is disposed between the semiconductor substrate and the absorption film, and reflects the reflected light.

Further, in the first aspect, the reflective film may have an opening of a different size from the size of the opening of the absorption film.

Also, in the first aspect, the absorption film may have the opening formed in a shape with a smaller opening area on the side of the semiconductor substrate than the opening area on the side of the on-chip lens.

Further, in the first aspect, the absorption film may have the opening formed in a tapered shape.

Also, in the first aspect, the absorption film may be formed with a plurality of layers having different absorption coefficients.

Further, in the first aspect, an absorbing material that absorbs the incident light may be dispersed in the absorption film.

Further, in the first aspect, the absorption film may have a thickness substantially equal to a diameter of the opening.

Also, in the first aspect, the imaging device may further include a second reflective film that is disposed on a different side of the semiconductor substrate from the side on which the absorption film is adjacent to the semiconductor substrate, and reflects the incident light having passed through the semiconductor substrate.

Also, in the first aspect, the imaging device may further include a scattering portion that scatters the reflected light.

Further, in the first aspect, the scattering portion may be formed with irregularities formed in a surface of the semiconductor substrate adjacent to the opening of the absorption film.

Further, in the first aspect, the scattering portion may be disposed on a side of the semiconductor substrate different from the side on which the absorption film is adjacent to the semiconductor substrate, and reflects and scatters the incident light having passed through the semiconductor substrate.

Also, in the first aspect, the imaging device may include a plurality of pixels each including the on-chip lens, the photoelectric conversion unit, and the absorption film.

Also, in the first aspect, the pixel may further include a color filter that transmits incident light of a predetermined wavelength in the incident light.

Further, in the first aspect, the color filter may transmit the incident light of a long wavelength.

Also, in the first aspect, the color filter may transmit red light.

Further, in the first aspect, the color filter may transmit infrared light.

Also, in the first aspect, the absorption film may be designed to have the position of the opening shifted in accordance with the incident angle of the incident light entering the pixel.

Further, in the first aspect, the absorption film may have a shape in which the opening is extended in accordance with the incident angle of the incident light entering the pixel.

Further, a second aspect of the present disclosure is an imaging apparatus that includes: an on-chip lens that condenses incident light; a photoelectric conversion unit that is formed in a semiconductor substrate and performs photoelectric conversion on the condensed incident light; an absorption film that is disposed adjacent to the semiconductor substrate, has an opening of substantially the same size as a condensing size of the condensed incident light, and absorbs reflected light of the incident light; and a processing circuit that processes an image signal generated on the basis of the photoelectric conversion.

As the aspects described above are adopted, reflected light is effectively absorbed while the incident light to be condensed is transmitted.

### BRIEF DESCRIPTION OF DRAWINGS

FIG. 1 is a diagram showing an example configuration of an imaging device according to an embodiment of the present disclosure.

FIG. 2 is a cross-sectional diagram showing an example configuration of a pixel according to a first embodiment of the present disclosure.

FIG. 3 is diagrams showing example configurations of pixels according to the first embodiment of the present disclosure.

FIG. 4 is a diagram showing an example of reflected light absorption according to the first embodiment of the present disclosure.

FIG. 5 is a cross-sectional diagram showing another example configuration of a pixel according to the first embodiment of the present disclosure.

FIG. 6 is a cross-sectional diagram showing an example configuration of a pixel according to a second embodiment of the present disclosure.

FIG. 7 is a cross-sectional diagram showing another example configuration of a pixel according to the second embodiment of the present disclosure.

FIG. 8 is a cross-sectional diagram showing an example configuration of a pixel according to a third embodiment of the present disclosure.

FIG. 9 is a diagram showing an example of reflected light absorption according to the third embodiment of the present disclosure.

FIG. 10 is a cross-sectional diagram showing an example configuration of a pixel according to a fourth embodiment of the present disclosure.

FIG. 11 is a cross-sectional diagram showing an example configuration of a pixel according to a fifth embodiment of the present disclosure.

FIG. 12 is a cross-sectional diagram showing an example configuration of a pixel according to a sixth embodiment of the present disclosure.

FIG. 13 is a cross-sectional diagram showing example configurations of pixels according to a seventh embodiment of the present disclosure.

FIG. 14 is diagrams showing example configurations of pixels according to an eighth embodiment of the present disclosure.

FIG. 15 is a cross-sectional diagram showing example configurations of pixels according to a ninth embodiment of the present disclosure.

FIG. 16 is a diagram showing example configurations of pixels according to the ninth embodiment of the present disclosure.

FIG. 17 is a cross-sectional diagram showing example configurations of pixels according to a tenth embodiment of the present disclosure.

FIG. 18 is a block diagram showing a schematic example configuration of a camera that is an example of an imaging apparatus to which the present disclosure can be applied.

### MODES FOR CARRYING OUT THE INVENTION

Next, modes for carrying out the present disclosure (the modes will be hereinafter referred to as embodiments) are described with reference to the drawings. In the drawings mentioned below, the same or similar components are denoted by the same or similar reference numerals. Further, explanation of the embodiments will be made in the following order.

1. First Embodiment

2. Second Embodiment

3. Third Embodiment

4. Fourth Embodiment

5. Fifth Embodiment

6. Sixth Embodiment

7. Seventh Embodiment

8. Eighth Embodiment

9. Ninth Embodiment

10. Tenth Embodiment

11. Example application to a camera

### 1. First Embodiment

[Configuration of an Imaging Device]

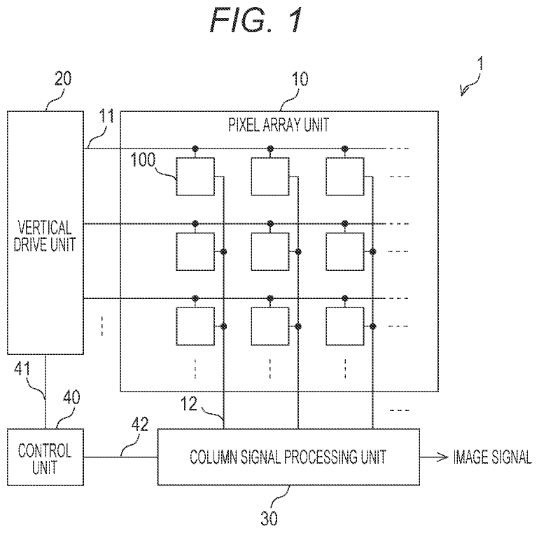

FIG. 1 is a diagram showing an example configuration of an imaging device according to an embodiment of the present disclosure. An imaging device 1 in this drawing includes a pixel array unit 10, a vertical drive unit 20, a column signal processing unit 30, and a control unit 40.

The pixel array unit 10 is formed with pixels 100 arranged in a two-dimensional grid pattern. Here, a pixel 100 generates an image signal in accordance with emitted light. This pixel 100 includes a photoelectric conversion unit that generates electric charges in accordance with the emitted light. The pixel 100 further includes a pixel circuit. This pixel circuit generates an image signal based on the electric charges generated by the photoelectric conversion unit. The generation of the image signal is controlled by a control signal generated by the vertical drive unit 20 described later. In the pixel array unit 10, signal lines 11 and 12 are arranged in an X-Y matrix. The signal lines 11 are signal lines that transmit control signals for the pixel circuits in the pixels 100, are provided for the respective rows in the pixel array unit 10, and are designed to be shared by the pixels 100 aligned in each row. The signal lines 12 are signal lines that transmit image signals generated by the pixel circuits of the pixels 100, are provided for the respective columns in the pixel array unit 10, and are designed to be shared by the pixels 100 aligned in each column. These photoelectric conversion units and pixel circuits are formed in a semiconductor substrate.

The vertical drive unit 20 generates control signals for the pixel circuits of the pixels 100. This vertical drive unit 20 transmits the generated control signals to the pixels 100 via the signal lines 11 in the drawing. The column signal processing unit 30 processes image signals generated by the pixels 100. This column signal processing unit 30 processes the image signals transmitted from the pixels 100 via the signal lines 12 in the drawing. The processing at the column signal processing unit 30 corresponds to analog-to-digital conversion for converting analog image signals generated in the pixels 100 into digital image signals, for example. The image signals processed by the column signal processing unit 30 are output as image signals of the imaging device 1. The control unit 40 controls the entire imaging device 1. This control unit 40 generates and outputs control signals for controlling the vertical drive unit 20 and the column signal processing unit 30, to control the imaging device 1. The control signals generated by the control unit 40 are transmitted to the vertical drive unit 20 and the column signal processing unit 30 through signal lines 41 and 42, respectively.

Note that the imaging device 1 in the drawing is an example of the imaging apparatus disclosed in the claims. The pixel array unit 10 in the drawing is an example of the imaging device described in the claims. The column signal processing unit 30 in the drawing is an example of the processing circuit described in the claims.

[Configuration of a Pixel]

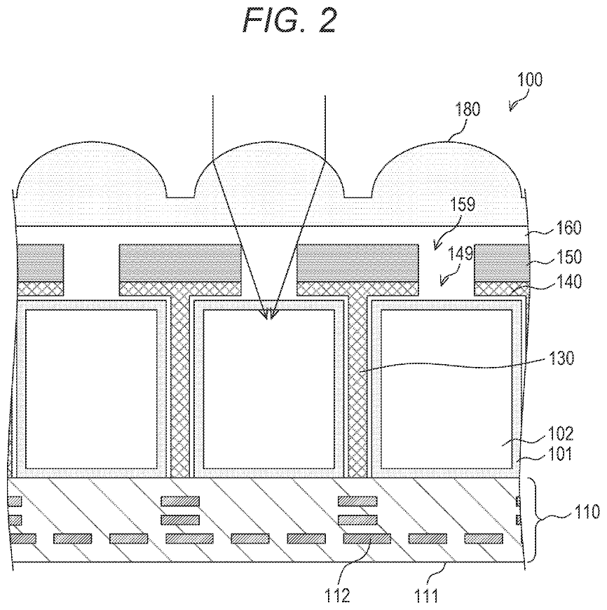

FIG. 2 is a cross-sectional diagram showing an example configuration of a pixel according to a first embodiment of the present disclosure. This drawing is a cross-sectional diagram showing an example configuration of a pixel 100. A pixel 100 in the drawing includes a semiconductor substrate 101, a wiring region 110, a reflective film 140, an absorption film 150, a protective film 160, and an on-chip lens 180.

The semiconductor substrate 101 is a semiconductor substrate in which the semiconductor region (diffusion region) of the elements forming the photoelectric conversion unit and the pixel circuit described above is formed. This semiconductor substrate 101 may be formed with silicon (Si), for example. The elements such as the photoelectric conversion unit are disposed in a well region formed in the semiconductor substrate 101. For convenience, it is assumed that the semiconductor substrate 101 in the drawing forms a p-type well region. As an n-type semiconductor region is formed in this p-type well region, the diffusion region of the element can be formed. In the semiconductor substrate 101 in the drawing, an n-type semiconductor region 102 forming a photoelectric conversion unit is shown as an example of the element. A photodiode formed by a p-n junction at the interface between the n-type semiconductor region 102 and the surrounding p-type well region corresponds to the photoelectric conversion unit. When the n-type semiconductor region 102 is irradiated with incident light, photoelectric conversion occurs. The electric charges generated by the photoelectric conversion are accumulated in the n-type semiconductor region 102. An image signal is generated by the pixel circuit (not shown) on the basis of the accumulated electric charges.

Note that a separation region 130 can be disposed at the boundary between the pixels 100 in the semiconductor substrate 101 in the drawing. The separation region 130 optically separates the pixels 100 from each other. Specifically, a film that reflects incident light is disposed as the separation region 130 between the pixels 100, so that leakage of the incident light to the adjacent pixels 100 is prevented. Thus, crosstalk between the pixels 100 can be prevented. The separation region 130 can be formed with a metal such as tungsten (W), for example. Note that a fixed charge film and an insulating film can be disposed between the separation region 130 and the semiconductor substrate 101. The fixed charge film is a film that is disposed at the interface with the semiconductor substrate 101 and pins the surface level of the semiconductor substrate 101. Meanwhile, the insulating film is a film that is disposed between the fixed charge film and the separation region 130, and insulates the separation region 130. Such a separation region 130 can be formed by forming the fixed charge film and the insulating film on the surface of a groove formed in the semiconductor substrate 101 and burying a metal such as W therein. As the separation region 130 including such an insulating film is provided, the pixels 100 can also be electrically isolated from each other.

The wiring region 110 is a region that is disposed adjacent to the surface of the semiconductor substrate 101 and has wiring lines formed therein to transmit signals. The wiring region 110 in the drawing includes a wiring layer 112 and an insulating layer 111. The wiring layer 112 is a conductor that transmits a signal to an element in the semiconductor substrate 101. The wiring layer 112 can be formed with a metal such as copper (Cu) or tungsten (W). The insulating layer 111 insulates the wiring layer 112. The insulating layer 111 can be formed with silicon oxide (SiO₂), for example. Note that the wiring layer 112 and the insulating layer 111 can be formed as multilayers. This drawing shows an example of a wiring line formed in three layers. The wiring layers 112 disposed in different layers can be connected to each other by a via plug not shown in the drawing.

Note that the imaging device 1 in the drawing corresponds to a back-illuminated imaging device in which incident light is emitted onto the photoelectric conversion unit from the back surface side of the semiconductor substrate 101. Incident light that enters the semiconductor substrate 101 from the object via the on-chip lens 180, absorption film 150, and the reflective film 140, which will be described later, is absorbed by the semiconductor substrate 101 and is photoelectrically converted. However, incident light that has not been absorbed by the semiconductor substrate 101 passes through the semiconductor substrate 101, turns into transmitted light, and enters the wiring region 110. Part of the transmitted light that has entered the wiring region 110 is reflected by the wiring layer 112 to turn into reflected light, and again enters the semiconductor substrate 101. As the reflected light re-enters the semiconductor substrate 101 and is photoelectrically converted, the sensitivity of the pixel 100 is improved. However, when the reflected light having passed through the semiconductor substrate 101 is released to the outside of the pixel 100, is reflected by the housing or the like, and re-enters the imaging device 1, flare or the like occurs, and image quality is degraded.

The reflective film 140 is disposed adjacent to the back surface of the semiconductor substrate 101, to transmit incident light from the object and reflect reflected light. The reflective film 140 has an opening 149 in its central portion, and transmits incident light condensed by the later-described on-chip lens 180 through the opening 149. The reflective film 140 also reflects the above-mentioned reflected light again, and causes the reflected light to enter the semiconductor substrate 101, to reduce leakage of the reflected light to the outside of the pixel 100. The reflective film 140 can be formed with a metal such as W, like the separation region 130. Further, the reflective film 140 can be formed at the same time as the separation region 130. Specifically, a material film is also formed on the back surface of the semiconductor substrate 101 when the metal to be the material of the separation region 130 is buried in the groove formed in the semiconductor substrate 101. The reflective film 140 can be manufactured by forming the opening 149 in the material film that has been formed. The opening 149 can be designed to have substantially the same size as the size of incident light condensing by the on-chip lens 180.

The absorption film 150 is disposed on the back surface of the semiconductor substrate 101, to transmit incident light from the object and absorb reflected light. The absorption film 150 has an opening 159 in the central portion, and, through the opening 159, transmits incident light condensed by the on-chip lens 180. The absorption film 150 also absorbs reflected light, to reduce leakage of the reflected light to the outside of the pixel 100. The absorption film 150 in the drawing is disposed adjacent to the reflective film 140, and absorbs the reflected light that has passed through the opening 149 of the reflective film 140. The absorption film 150 can be formed with a film in which an absorbing material that absorbs incident light is dispersed, for example. For example, a pigment that absorbs light, such as carbon black or titanium oxide, is used as the absorbing material, and the absorption film 150 can be formed with a film in which the pigment is dispersed in resin or the like. Such an absorption film 150 can be manufactured in the following manner: a resin film having a pigment dispersed therein is formed adjacent to the reflective film 140, and the opening 159 is then formed. Note that the opening 159 can be formed by dry etching, or by wet etching using a chemical solution. Note that an absorption film 150 containing a dye-based absorbing material such as an infrared absorber can also be used.

The protective film 160 is a film that insulates and protects the back surface side of the semiconductor substrate 101. The protective film 160 in the drawing is disposed adjacent to the absorption film 150, and further planarizes the back surface side of the semiconductor substrate 101 on which the reflective film 140 and the absorption film 150 are disposed. The protective film 160 can be formed with SiO₂, for example. Note that it is also possible to adopt a configuration in which a protective film is disposed on the front surface of the reflective film 140. Specifically, after the reflective film 140 is formed, a protective film covering the reflective film 140, such as a SiO₂ film, is disposed thereon, for example. After that, the absorption film 150 is formed. As a result, the protective film 160 can be disposed in a region between the reflective film 140 and the absorption film 150.

The on-chip lens 180 is a lens that is provided for each pixel 100 and condenses incident light from the object onto the photoelectric conversion unit of the semiconductor substrate 101. The on-chip lens 180 is formed in a convex-lens shape, and condenses incident light. The on-chip lens 180 in the drawing condenses incident light onto the photoelectric conversion unit via the opening 159 of the absorption film 150 and the opening 149 of the reflective film 140 described above. Arrows in the drawing indicates the state of light condensing by the on-chip lens 180. The on-chip lens 180 can be formed with an organic material such as resin or an inorganic material such as silicon nitride (SiN), for example.

As shown in the drawing, incident light is condensed by the on-chip lens 180, and a focal point is formed in a region of the semiconductor substrate 101. Light that has entered the on-chip lens 180 is gradually narrowed while traveling from the on-chip lens 180 to the semiconductor substrate 101, and the condensing size, which is the irradiation range of incident light in the horizontal direction, is narrowed. As the opening 159 of the absorption film 150 is designed to have a size substantially equal to the size of the incident light condensing, it is possible to reduce leakage of reflected light through the opening 159 while preventing the absorption film 150 from blocking (vignetting) the incident light condensed by the on-chip lens 180. As the opening 149 of the reflective film 140 is also designed to have substantially the same size as the light condensing size, it is possible to reduce leakage of reflected light through the opening 149 while preventing vignetting of the condensed incident light.

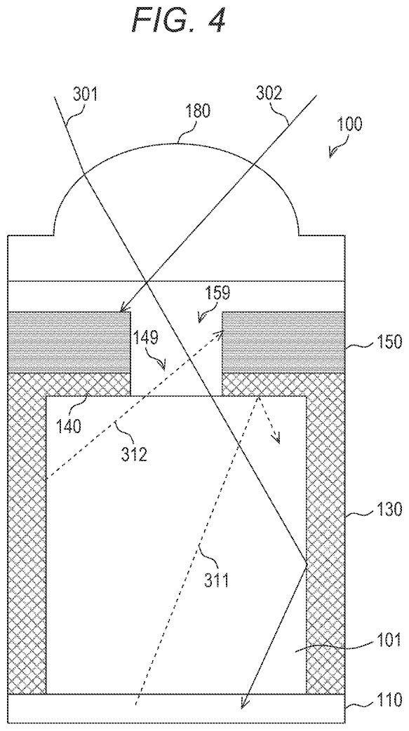

The absorption film 150 preferably has a thickness substantially equal to the diameter of the opening 159. As the thickness of the absorption film 150 is made greater, the wall surface of the opening 159, which is a through hole, becomes wider, and the reflected light (reflected light 312 shown in FIG. 4 described later) to be captured by the wall surface of the opening 159 increases. As the thickness of the absorption film 150 is made greater, the reflected light absorption capacity can also be increased. This is because the absorption coefficient, which is the ratio between incident light and transmitted light in the absorption film 150, is proportional to the absorbing material contained in the absorption film 150. Meanwhile, it is necessary to increase the area of the opening 159 as the thickness of the absorption film 150 increases. This is to prevent vignetting of incident light. However, when the area of the opening 159 is increased, reflected light passing through the opening 159 increases. Therefore, the absorption film 150 having a thickness substantially equal to the diameter of the opening 159 is provided, so that reflected light passing through the opening 159 can be reduced while the absorption coefficient of the absorption film 150 is improved.

[Planar Configurations of Pixels]

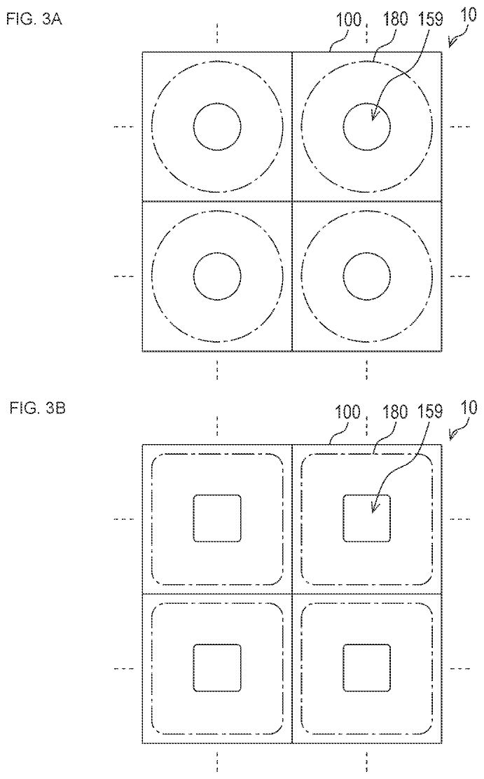

FIG. 3 is diagrams showing example configurations of pixels according to the first embodiment of the present disclosure. The drawing is top views showing example configurations of pixels 100 disposed in the pixel array unit 10, and is diagrams each showing the layout of an on-chip lens 180 and an absorption film 150. In the drawing, a dot-and-chain line indicates the shape of the bottom surface of an on-chip lens 180.

A in the drawing is a diagram showing an example of a pixel 100 in which an on-chip lens 180 designed to have a circular bottom surface is disposed. A solid-line circle in A in the drawing indicates the opening 159 of an absorption film 150.

B in the drawing is a diagram showing an example of a pixel 100 in which an on-chip lens 180 designed to have a rectangular bottom surface is disposed. In B in the drawing, the opening 159 of the absorption film 150 can be formed in a rectangular shape.

In this manner, the opening 159 of the absorption film 150 can be changed in accordance with the shape of the bottom surface of the on-chip lens 180. Note that the opening 149 of the reflective film 140 can also be formed in a shape similar to the opening 159 of the absorption film 150.

[Absorption of Reflected Light]

FIG. 4 is a diagram showing an example of reflected light absorption according to the first embodiment of the present disclosure. The drawing is a diagram showing a simplified pixel 100, and is a diagram showing the trajectories of incident light and reflected light in the pixel 100. In the drawing, solid-line arrows indicate incident light, and dashed-line arrows indicate reflected light. Incident light 301 indicates incident light that is reflected by the separation region 130 after entering the semiconductor substrate 101. Incident light 302 indicates incident light that obliquely enters the pixel 100. The incident light 302 is assumed to be incident light that indirectly enters the pixel 100 after light from the object is reflected by an inner surface of the housing or the like in which the imaging device 1 is contained, and is incident light that causes noise such as flare when imaged by the pixel 100. Such incident light 302 is absorbed by the absorption film 150. Reflected light 311 indicates reflected light that is reflected again by the reflective film 140 after entering the semiconductor substrate 101 from the wiring region 110.

Meanwhile, reflected light 312 indicates reflected light that passes through the opening 149 of the reflective film 140. The reflected light 312 enters the side surface of the opening 159 of the absorption film 150, and is absorbed. As the absorption film 150 is provided in this manner, leakage of reflected light to the outside of the pixel 100 can be reduced.

[Other Configurations of Pixels]

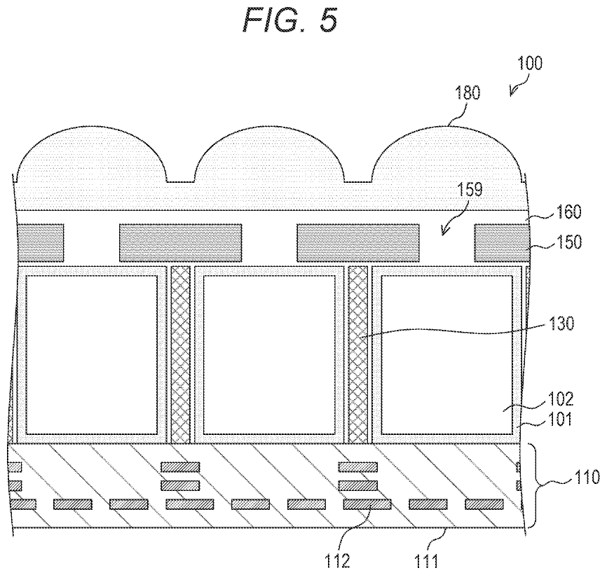

FIG. 5 is a cross-sectional diagram showing another example configuration of a pixel according to the first embodiment of the present disclosure. Like FIG. 2, this drawing is a cross-sectional diagram showing an example configuration of a pixel 100. The pixel 100 differs from the pixel 100 shown in FIG. 2 in not including the reflective film 140. In the pixel 100 in the drawing, the above-described reflected light 311 is absorbed by the absorption film 150.

As described above, the imaging device 1 according to the first embodiment of the present disclosure can reduce reflected light from the imaging device 1 by providing the absorption film 150 in the pixel 100 and absorbing reflected light.

### 2. Second Embodiment

The imaging device 1 of the first embodiment described above includes the absorption film 150 having the cylindrical opening 159. However, an imaging device 1 according to a second embodiment of the present disclosure differs from the above-described first embodiment in including an absorption film having an opening in a shape depending on the light condensing to be performed by the on-chip lens 180.

[Configuration of a Pixel]

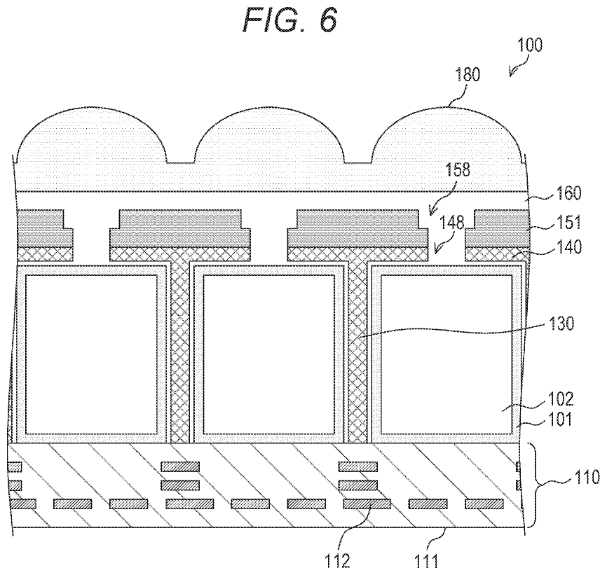

FIG. 6 is a cross-sectional diagram showing an example configuration of a pixel according to the second embodiment of the present disclosure. Like FIG. 2, this drawing is a cross-sectional diagram showing an example configuration of a pixel 100. The pixel 100 differs from the pixel 100 described with reference to FIG. 2 in including an absorption film 151 in place of the absorption film 150.

In the absorption film 151, an opening 158 is formed in place of the opening 159. The opening 158 is an opening that has different opening areas on the side close to the on-chip lens 180 and the side close to the semiconductor substrate 101. A step is formed in the opening 158 in the drawing, and the opening area on the side close to the semiconductor substrate 101 is smaller than the opening area on the side close to the on-chip lens 180. As the opening area on the side adjacent to the on-chip lens 180 is made larger, and the opening area on the opposite side is made smaller as above, the opening can be formed in a shape depending on the reduction in the size of light condensing by the on-chip lens 180. As the opening area on the side close to the semiconductor substrate 101 is made smaller, more reflected light can be absorbed.

[Other Configurations of Pixels]

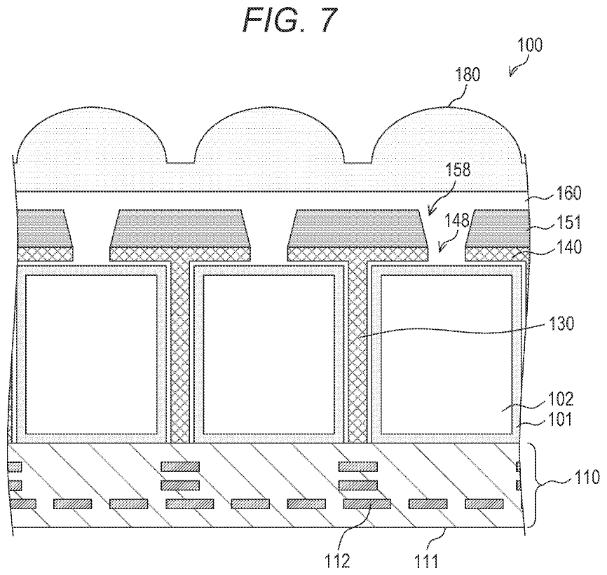

FIG. 7 is a cross-sectional diagram showing another example configuration of a pixel according to the second embodiment of the present disclosure. The absorption film 151 in the drawing differs from the absorption film 151 in FIG. 6 in that the opening 158 is formed in a tapered shape. As any step is not formed in the opening 158 in the drawing, vignetting of incident light at a step portion does not occur. With this arrangement, the opening area on the side close to the semiconductor substrate 101 can be made even smaller, and reflected light absorption efficiency can be improved.

The other components of the imaging device 1 are similar to the components of the imaging device 1 described in the first embodiment of the present disclosure, and therefore, explanation of them is not made herein.

As described above, the imaging device 1 according to the second embodiment of the present disclosure includes the absorption film 151 having the opening 158 that has a smaller opening area in the plane close to the semiconductor substrate 101 than in the plane close to the on-chip lens 180. With this arrangement, more reflected light can be absorbed, and leakage of reflected light can be further reduced.

### 3. Third Embodiment

In the imaging device 1 of the second embodiment described above, reflected light is absorbed by the absorption film 151. On the other hand, an imaging device 1 according to a third embodiment of the present disclosure differs from the above-described second embodiment in that reflected light is absorbed by a plurality of stacked absorption films.

[Configuration of a Pixel]

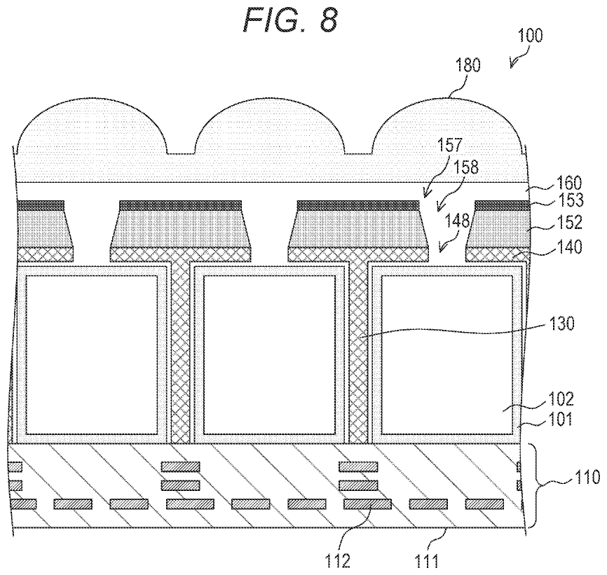

FIG. 8 is a cross-sectional diagram showing an example configuration of a pixel according to a third embodiment of the present disclosure. Like FIG. 7, this drawing is a cross-sectional diagram showing an example configuration of a pixel 100. The pixel 100 differs from the pixel 100 described with reference to FIG. 7 in including absorption films 152 and 153 in place of the absorption film 151.

The absorption film 152 is an absorption film that is designed to have a relatively low ratio of the absorbing material to resin and have a relatively great thickness. An opening 158 similar to that of the absorption film 151 is formed in the absorption film 152. Meanwhile, the absorption film 153 is an absorption film that is designed to have a relatively high ratio of the absorbing material to resin and have a relatively small thickness. In the absorption film 153, an opening 157 having the same diameter as the opening 158 on the side close to the on-chip lens 180 can be formed. In this manner, the plurality of absorption films 152 and 153 having different absorption coefficients is disposed in the pixel 100 in the drawing.

As described above, the absorption films 152 and 153 can be formed by dispersing an absorbing material such as a pigment in resin, and the absorption coefficient can be increased with an increase in the content of the absorbing material. However, it is difficult to process an absorption film in which a large amount of an absorbing material is dispersed. Specifically, it is difficult to perform etching on the absorption film 152 to form the opening 158. This is because etching is not easily performed on a pigment, compared with etching on resin. Therefore, the content of the absorbing material in the absorption film 152 designed to have a relatively great thickness and have the tapered opening 158 is reduced. The absorption film 153 designed to contain an increased amount of the absorbing material and have a small thickness is stacked on the absorption film 152. With this arrangement, it is possible to provide absorption films that can be easily processed while maintaining a reflected light absorption capacity.

[Absorption of Reflected Light]

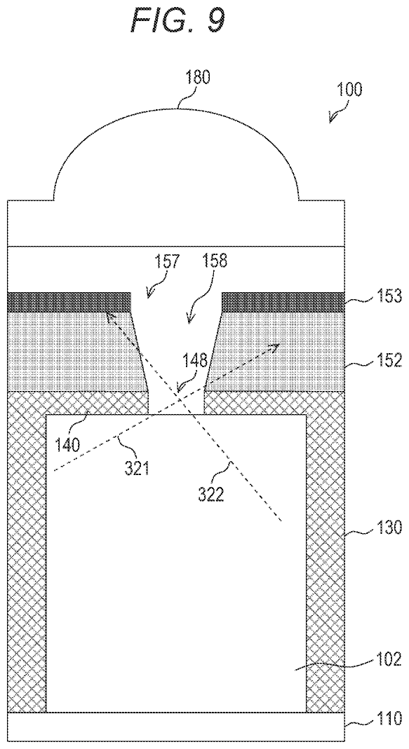

FIG. 9 is a diagram showing an example of reflected light absorption according to the third embodiment of the present disclosure. Like FIG. 4, this drawing is a diagram showing trajectories of reflected light in a pixel 100. Of the reflected light passing through the opening 148 of the reflective film 140, reflected light 321 that enters the absorption film 152 at a large incident angle is absorbed by the absorption film 152. On the other hand, reflected light 322 that enters the absorption film 152 at a small angle passes through the absorption film 152. However, the light then enters the absorption film 153 and is absorbed.

The other components of the imaging device 1 are similar to the components of the imaging device 1 described in the second embodiment of the present disclosure, and therefore, explanation of them is not made herein.

As described above, the imaging device 1 according to the third embodiment of the present disclosure includes a plurality of absorption films having different absorption coefficients. Thus, it is possible to provide absorption films that can be easily processed while maintaining a reflected light absorption capacity.

### 4. Fourth Embodiment

The imaging device 1 of the first embodiment described above absorbs light reflected by the semiconductor substrate 101 and the wiring region 110. On the other hand, an imaging device 1 according to a fourth embodiment of the present disclosure differs from the above-described first embodiment in that reflected light is absorbed after being scattered.

[Configuration of a Pixel]

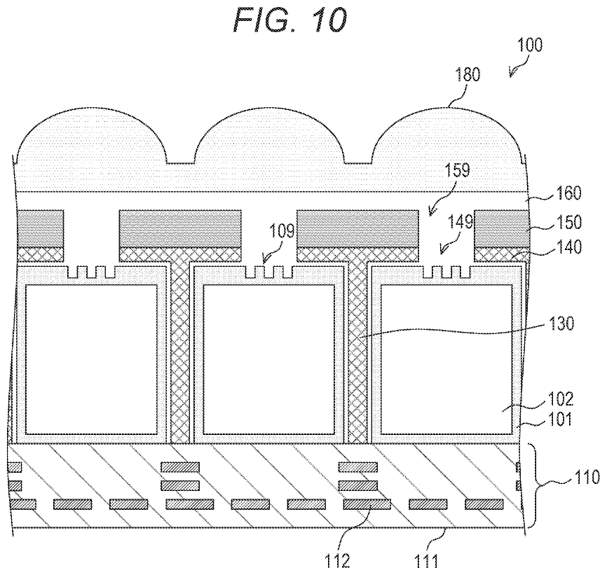

FIG. 10 is a cross-sectional diagram showing an example configuration of a pixel according to the fourth embodiment of the present disclosure. Like FIG. 2, this drawing is a cross-sectional diagram showing an example configuration of a pixel 100. The pixel 100 differs from the pixel 100 described with reference to FIG. 2 in further including a scattering portion 109 on the back surface side of the semiconductor substrate 101.

The scattering portion 109 scatters incident light and reflected light. The scattering portion 109 in the drawing is formed with irregularities formed in the back surface of the semiconductor substrate 101, and is located in the vicinity of the opening 159 of the absorption film 150. The absorption film 150 in the drawing absorbs the reflected light scattered by the scattering portion 109. As the reflected light leaking to the outside of the pixel 100 without being absorbed by the absorption film 150 is scattered by the scattering portion 109, the reflected light is dispersed and emitted over a wide range. Accordingly, flare and the like can be made inconspicuous. The scattering portion 109 can be formed by performing etching on part of the back surface of the semiconductor substrate 101, for example.

The other components of the imaging device 1 are similar to the components of the imaging device 1 described in the first embodiment of the present disclosure, and therefore, explanation of them is not made herein.

As described above, the imaging device 1 according to the fourth embodiment of the present disclosure includes the scattering portion 109, and scatters reflected light leaking from the pixel 100. Thus, image quality can be further improved.

### 5. Fifth Embodiment

In the imaging device 1 of the first embodiment described above, the reflective film 140 is disposed on the back surface side of the semiconductor substrate 101. On the other hand, an imaging device 1 according to a fifth embodiment of the present disclosure differs from the above-described first embodiment in further including a reflective film on the front surface side of the semiconductor substrate 101.

[Configuration of a Pixel]

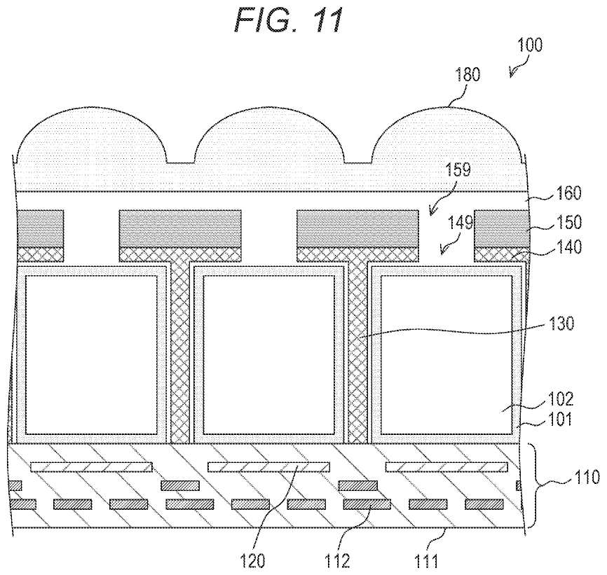

FIG. 11 is a cross-sectional diagram showing an example configuration of a pixel according to the fifth embodiment of the present disclosure. Like FIG. 2, this drawing is a cross-sectional diagram showing an example configuration of a pixel 100. The pixel 100 differs from the pixel 100 described with reference to FIG. 2 in further including a reflective film 120 on the front surface side of the semiconductor substrate 101.

The reflective film 120 reflects transmitted light. The reflective film 120 is disposed in the wiring region 110, and is formed in a shape covering the front surface side of the semiconductor substrate 101 of the pixel 100. As the reflective film 120 is provided, transmitted light that has passed through the semiconductor substrate 101 can be reflected toward the semiconductor substrate 101. As a result, incident light contributing to photoelectric conversion can be increased. Compared with the imaging device 1 in FIG. 2, the conversion efficiency of the pixel 100 can be improved. The reflective film 120 can be formed with a metal, like the reflective film 140. Alternatively, the reflective film 120 can be formed with the wiring layer 112. Note that the reflective film 120 is an example of the second reflective film disclosed in the claims.

The other components of the imaging device 1 are similar to the components of the imaging device 1 described in the first embodiment of the present disclosure, and therefore, explanation of them is not made herein.

As described above, including the reflective film 120, the imaging device 1 according to the fifth embodiment of the present disclosure reflects transmitted light toward the semiconductor substrate 101. Thus, conversion efficiency can be improved.

### 6. Sixth Embodiment

In the imaging device 1 of the fourth embodiment described above, the scattering portion 109 is formed in the back surface of the semiconductor substrate 101. On the other hand, an imaging device 1 according to a sixth embodiment of the present disclosure differs from the above-described fourth embodiment in that a scattering portion is formed on the front surface side of the semiconductor substrate 101.

[Configuration of a Pixel]

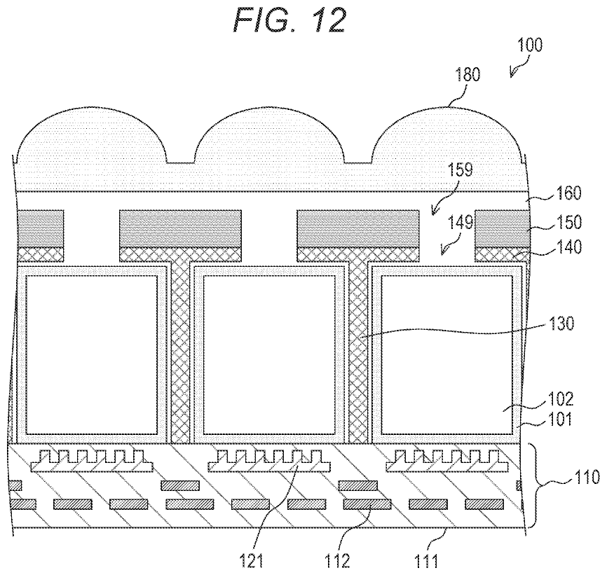

FIG. 12 is a cross-sectional diagram showing an example configuration of a pixel according to the sixth embodiment of the present disclosure. Like FIG. 2, this drawing is a cross-sectional diagram showing an example configuration of a pixel 100. The pixel 100 differs from the pixel 100 described with reference to FIG. 2 in further including a scattering portion 121 in the wiring region 110.

The scattering portion 121 reflects and scatters incident light that has passed through the semiconductor substrate 101. The scattering portion 121 in the drawing can be disposed in the wiring region 110 adjacent to the front surface of the semiconductor substrate 101. For the scattering portion 121, a metal film in which irregularities are formed can be used, for example. In this case, the scattering portion 121 can be formed with the same metal material as the wiring layer 112. As the scattering portion 121 is provided, incident light that has passed through the semiconductor substrate 101 is reflected, to enter the semiconductor substrate 101 again. Thus, the conversion efficiency of the pixel 100 can be improved. Further, as the reflected light from the scattering portion 121 is scattered, flare and the like can be made inconspicuous even in a case where light leaks from the pixel 100. The scattering portion 121 can be formed by performing etching on a surface of the insulating layer 111 to form irregularities, and stacking a metal film on the irregularities, for example.

The other components of the imaging device 1 are similar to the components of the imaging device 1 described in the fourth embodiment of the present disclosure, and therefore, explanation of them is not made herein.

As described above, including the scattering portion 121, the imaging device 1 according to the sixth embodiment of the present disclosure reflects transmitted light from the semiconductor substrate 101 and scatters reflected light leaking from the pixel 100. Thus, conversion efficiency can be improved while image quality is improved.

### 7. Seventh Embodiment

In the imaging device 1 of the first embodiment described above, incident light of all wavelengths enters the photoelectric conversion units of the pixels 100. On the other hand, an imaging device 1 according to a seventh embodiment of the present disclosure differs from the above-described first embodiment in that a color filter is provided for each pixel 100 to select incident light.

[Configuration of a Pixel]

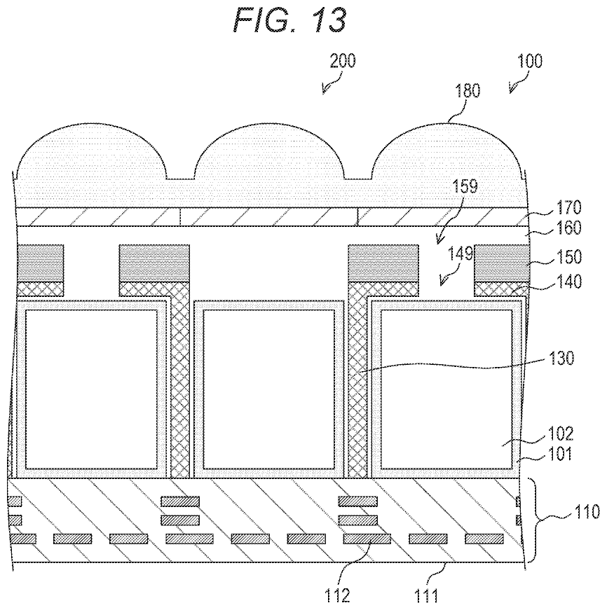

FIG. 13 is a cross-sectional diagram showing example configurations of pixels according to the seventh embodiment of the present disclosure. Like FIG. 2, this drawing is a cross-sectional diagram showing an example configuration of a pixel. The pixels differ from the pixels 100 described with reference to FIG. 2 in including a pixel 100 having a color filter 170 and further including a pixel 200.

The pixel 100 in the drawing includes a color filter 170. The color filter 170 is an optical filter that transmits incident light having a predetermined wavelength in entire incident light. As the color filter 170, a color filter 170 that transmits red light, green light, and blue light can be used, for example. In the pixel 100, a color filter 170 corresponding to any one of these colors can be provided. The on-chip lens 180 in the drawing condenses incident light onto the photoelectric conversion unit via the color filter 170. The photoelectric conversion unit generates an image signal of incident light having a wavelength with which the color filter 170 is compatible. By adopting the pixels 100 including the color filters 170, it is possible to obtain a color image. Further, a color filter that transmits infrared light can be adopted as a color filter 170.

Note that a color filter 170 that transmits incident light having a relatively long wavelength can be adopted as the color filter 170 of a pixel 100. Specifically, a color filter 170 that transmits infrared light and red light can be provided in a pixel 100. Incident light having a relatively long wavelength such as infrared light and red light is hardly absorbed by the semiconductor substrate 101, and thus, reaches a deep portion in the semiconductor substrate 101. In a case where the thickness of the semiconductor substrate 101 is small as in the back-illuminated imaging device 1 shown in the drawing, incident light having a long wavelength passes through the semiconductor substrate 101, and reflected light is easily generated. Therefore, in such a pixel 100, the absorption film 150 and the reflective film 140 described above are provided to reduce reflected light.

The pixel 200 is a pixel that includes the color filter 170 but does not include the absorption film 150 and the reflective film 140. The protective film 160 is provided in the regions of the absorption film 150 and the reflective film 140. A color filter 170 that transmits incident light having a relatively short wavelength can be provided as the color filter 170 of the pixel 200. Specifically, a color filter 170 that transmits green light and blue light can be provided in the pixel 200. Incident light having a relatively short wavelength, such as green light and blue light, is easily absorbed by the semiconductor substrate 101, and the rate at which reflected light passing through the semiconductor substrate 101 is generated is low. Accordingly, the absorption film 150 and the reflective film 140 can be omitted from the pixel 200 in which the color filter 170 compatible with green light and blue light is provided.

Note that the configuration of the imaging device 1 is not limited to this example. For example, the absorption film 150 and the reflective film 140 can be provided for all the pixels.

The other components of the imaging device 1 are similar to the components of the imaging device 1 described in the first embodiment of the present disclosure, and therefore, explanation of them is not made herein.

As described above, including the color filters 170, the imaging device 1 according to the seventh embodiment of the present disclosure can output a color image signal.

### 8. Eighth Embodiment

In the imaging device 1 of the first embodiment described above, the opening 159 of the absorption film 150 is located at the central portion of the pixel 100. On the other hand, an imaging device 1 according to an eighth embodiment of the present disclosure differs from the above-described first embodiment in that the position and the shape of the opening 159 are adjusted in accordance with the incident angle of incident light.

[Configuration of a Pixel]

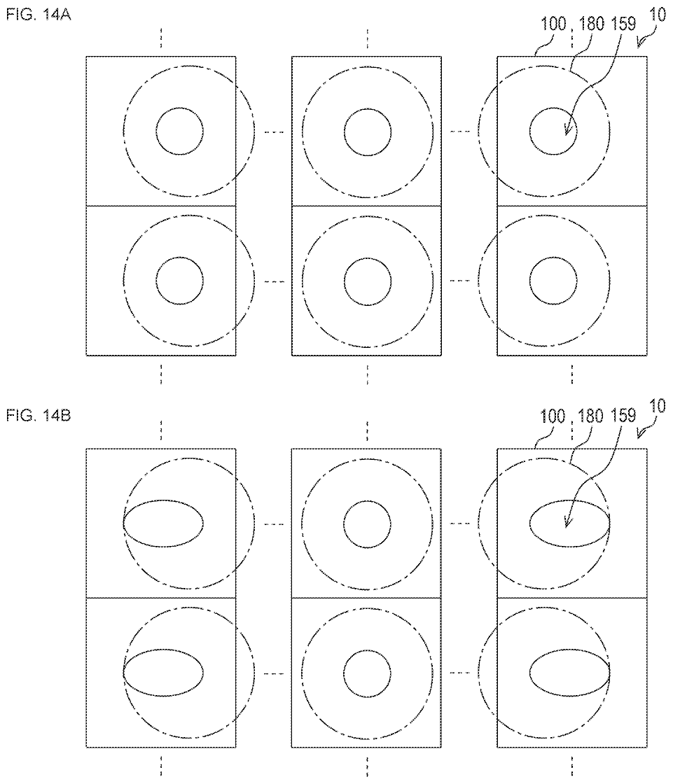

FIG. 14 is diagrams showing example configurations of pixels according to the eighth embodiment of the present disclosure. Like FIG. 3, this drawing is top views showing example configurations of pixels 100. The pixels 100 differ from the pixels 100 described with reference to FIG. 3 in including pixels 100 among which the position of the on-chip lens 180, the position of the opening 159 of the absorption film 150, and the like vary.

The drawing is diagrams showing pixels 100 that are arranged at the right and left edges and at the centers of the rows in the central portion of the pixel array unit 10 described with reference to FIG. 1. In A in the drawing, the pixels 100 arranged in the central portion of the pixel array unit 10 can have a configuration similar to that of the pixels 100 described with reference to FIG. 3. In the pixels 100 arranged at the edges, on the other hand, the on-chip lenses 180 are shifted toward the central portion of the pixel array unit 10. Likewise, the openings 159 of the absorption film 150 are also shifted toward the central portion of the pixel array unit 10.

An image of the object is formed on the pixel array unit 10 of the imaging device 1 by an imaging lens or the like. At this point of time, light from the object almost perpendicularly enters the pixels 100 in the central portion of the pixel array unit 10. On the other hand, light from the object obliquely enters the pixels 100 in the peripheral portions of the pixel array unit 10. Therefore, a difference is caused between the condensing positions of the incident light condensed by the on-chip lenses 180 and the positions of the photoelectric conversion units, and the sensitivity drops. To counter this, the on-chip lenses 180 are shifted in accordance with the incident angle of incident light, so that the light condensing positions can be adjusted. Such adjustment of the positions of the on-chip lenses 180 is called pupil correction. Like the on-chip lenses 180, the openings 159 of the absorption film 150 are also shifted in accordance with the incident angle of incident light. With this arrangement, vignetting of incident light for which the condensing positions are adjusted can be prevented.

B in the drawing is a diagram showing an example case where openings 157, instead of the openings 159, are formed in in the absorption film 150. The pixels 100 in B in the drawing have the openings 157 whose shapes are adjusted in accordance with the incident angle of incident light. Specifically, the openings 157 of the pixels 100 arranged in the peripheral portions of the pixel array unit 10 are each formed in a shape extending in a direction toward the central portion of the pixel array unit 10. With this arrangement, vignetting of incident light that obliquely enters can be prevented.

Note that the configuration of the imaging device 1 is not limited to this example. For example, the rectangular opening 159 described with reference to B of FIG. 3 can also be adopted. In that case, the positions and the shapes of the rectangular openings 159 are adjusted in accordance with the incident angle of incident light.

The other components of the imaging device 1 are similar to the components of the imaging device 1 described in the first embodiment of the present disclosure, and therefore, explanation of them is not made herein.

As described above, the imaging device 1 according to the eighth embodiment of the present disclosure can prevent a decrease in the sensitivity of the pixels 100 in the peripheral portions of the pixel array unit 10, by performing pupil correction.

### 9. Ninth Embodiment

The imaging device 1 of the second embodiment described above includes the reflective film 140 that has the opening 148 of substantially the same size as the opening 158 of the absorption film 151. On the other hand, an imaging device 1 according to a ninth embodiment of the present disclosure differs from the above-described second embodiment in including a reflective film 140 having an opening of a different size from that of the opening 158 of the absorption film 151.

[Configuration of a Pixel]

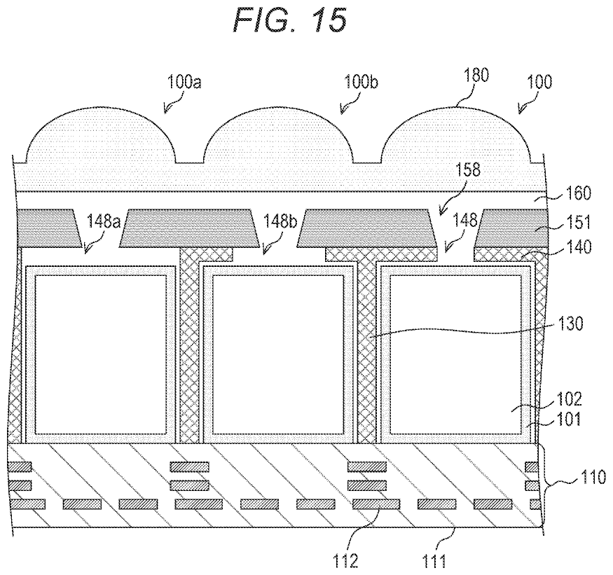

FIG. 15 is a cross-sectional diagram showing example configurations of pixels according to the ninth embodiment of the present disclosure. Like FIG. 7, this drawing is a cross-sectional diagram showing an example configuration of a pixel 100. The pixel 100 differs from the pixel 100 described with reference to FIG. 7 in including a reflective film 140 having an opening of a different size from that of the opening 158 of the absorption film 151.

The pixel 100 at the right end in the drawing is a pixel that includes the reflective film 140 having the opening 148, like the pixel 100 shown in FIG. 7. On the other hand, the reflective film 140 of a pixel 100a at the left end and the reflective film 140 of a pixel 100b at the center in the drawing each have an opening of a different size from that of the opening 158 of the absorption film 151.

The reflective film 140 of the pixel 100a has an opening 148a of substantially the same size as the region of the semiconductor substrate 101. That is, the reflective film 140 of the pixel 100a has a shape formed at a boundary of the pixel 100. Accordingly, in the pixel 100a, reflection of light on the back surface side of the semiconductor substrate 101 is greatly reduced. Reflected light that has been reflected by the wiring region 110 and passed through the semiconductor substrate 101 again is absorbed by the absorption film 151. Therefore, the pixel 100a is a pixel with a relatively low sensitivity.

The reflective film 140 of the pixel 100b has an opening 148b that is intermediate in size between the opening of the reflective film 140 in the pixel 100 and the opening of the reflective film 140 in the pixel 100a. Accordingly, the pixel 100b is intermediate in sensitivity between the pixel 100 and the pixel 100a.

As the sizes of the openings of the reflective film 140 are adjusted in this manner, the sensitivity of the pixel 100 can be adjusted. Note that, in a case where the opening 158 of the absorption film 151 is formed in a tapered shape, the opening 148 of the reflective film 140 is preferably formed in a size equal to or larger than the opening 158 of the absorption film 151. This is because, with such arrangement, vignetting of incident light can be reduced.

[Planar Configurations of Pixels]

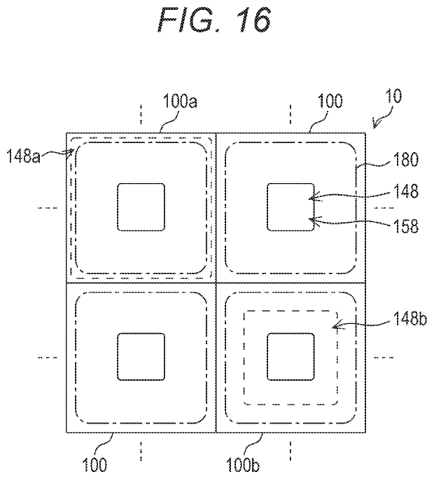

FIG. 16 is a diagram showing example configurations of pixels according to the ninth embodiment of the present disclosure. Like FIG. 3, this drawing is top views showing example configurations of pixels 100. Dotted lines in the drawing indicate openings in the reflective film 140. Note that, in a pixel 100, the opening 148 of the reflective film 140 has a shape overlapping the opening 158 of the absorption film 151.

As shown in the drawing, the opening 148a of the reflective film 140 of the pixel 100a occupies a wide area of the back surface of the pixel. The pixel 100b has the opening 148b that is intermediate in size between the opening of the reflective film 140 in the pixel 100 and the opening of the reflective film 140 in the pixel 100a. The pixel 100, the pixel 100b, and the pixel 100a in the drawing correspond to a high-sensitivity pixel, an intermediate-sensitivity pixel, and a low-sensitivity pixel, respectively. As these pixels are switched and used in accordance with the quantity of incident light, the dynamic range of the imaging device 1 can be expanded. Also, the imaging device 1 can be made compatible with a so-called high dynamic range (HDR).

Note that the configuration of a pixel 100 is not limited to this example. For example, the openings in the reflective film 140 may be formed in a tapered shape. Also, the openings in the reflective film 140 can be designed to have more sizes that vary stepwise.

The other components of the imaging device 1 are similar to the components of the imaging device 1 described in the third embodiment of the present disclosure, and therefore, explanation of them is not made herein.

As described above, in the imaging device 1 according to the ninth embodiment of the present disclosure, the reflective film 140 having the opening 148 of a different size from the opening 158 of the absorption film 151 is provided in a pixel 100, so that the sensitivity of the pixel can be adjusted.

### 10. Tenth Embodiment

The imaging device 1 of the ninth embodiment described above includes the reflective film 140 that has the opening 149 of a different size from the opening 158 of the absorption film 151. On the other hand, an imaging device 1 according to a tenth embodiment of the present disclosure differs from the above-described ninth embodiment in including a wiring region 110 that includes a reflective film 120.

[Configuration of a Pixel]

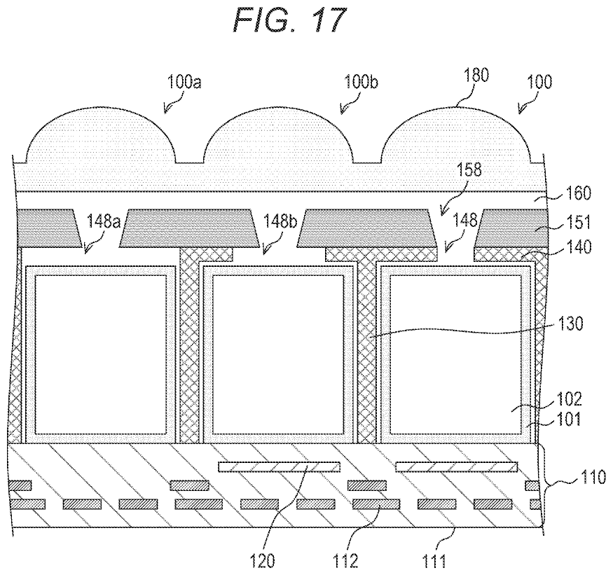

FIG. 17 is a cross-sectional diagram showing example configurations of pixels according to the tenth embodiment of the present disclosure. Like FIG. 15, this drawing is a cross-sectional diagram showing example configurations of pixels 100. The pixels 100 differ from the pixels 100 described with reference to FIG. 17 in further including the reflective film 120 on the front surface side of the semiconductor substrate 101.

The reflective film 120 described with reference to FIG. 11 is provided in the pixels 100 and 100b in the drawing. With this arrangement, the sensitivity of the pixels 100 and 100b can be increased. On the other hand, the reflective film 120 is not provided in the pixel 100a in the drawing, and therefore, the sensitivity thereof remains low. As the reflective film 120 is added to adjust sizes in this manner, the sensitivity of the pixel 100 and the like can be further adjusted.

The other components of the imaging device 1 are similar to the components of the imaging device 1 described in the ninth embodiment of the present disclosure, and therefore, explanation of them is not made herein.

As described above, in the imaging device 1 according to the tenth embodiment of the present disclosure, the size of the opening 148 of the reflective film 140 and the size of the reflective film 120 in the pixel 100 are adjusted, so that the sensitivity of the pixel 100 and the like can be adjusted over a wide range.

Note that the configuration of the absorption film of the second embodiment of the present disclosure can be applied to other embodiments. Specifically, the shape of the absorption film 151 described with reference to FIGS. 6 and 7 can be applied to the absorption films shown in FIGS. 5 and 8, and 10 to 14.

The configuration of the absorption film of the third embodiment of the present disclosure can be applied to other embodiments. Specifically, the absorption films 152 and 153 described with reference to FIG. 8 can be applied to the absorption films shown in FIGS. 5 to 7, and 10 to 15.

The configuration of a pixel of the fourth embodiment of the present disclosure can be applied to other embodiments. Specifically, the scattering portion 109 described with reference to FIG. 10 can be applied to the pixels 100 shown in FIGS. 5 to 8, and 11 to 14.

The configuration of the pixels of the fifth embodiment of the present disclosure can be applied to other embodiments. Specifically, the reflective film 120 described with reference to FIG. 11 can be applied to the pixels 100 shown in FIGS. 5 to 8, 10, 13, and 14.

The configuration of the pixels of the sixth embodiment of the present disclosure can be applied to other embodiments. Specifically, the scattering portion 121 described with reference to FIG. 12 can be applied to the pixels 100 shown in FIGS. 5 to 8, 10, 13 to 15, and 17.

The configuration of the pixels of the seventh embodiment of the present disclosure can be applied to other embodiments. Specifically, the color filters 170 described with reference to FIG. 13 can be applied to the pixels 100 shown in FIGS. 5 to 8, 10 to 12, 14, 15, and 17. Also, the pixels 100 and 200 described with reference to FIG. 13 can be applied to the pixel array units 10 shown in FIGS. 5 to 8, 10 to 12, 14, 15, and 17.

The configuration of the pixels of the eighth embodiment of the present disclosure can be applied to other embodiments. Specifically, the absorption film 150 described with reference to FIG. 14 can be applied to the pixels 100 shown in FIGS. 5 to 8, 10, 13, 15, and 17.

The configuration of the pixels of the ninth embodiment of the present disclosure can be applied to other embodiments. Specifically, the reflective film 140 described with reference to FIG. 15 can be applied to the pixels 100 shown in FIGS. 2, 6, 8, 10, 12, 13, and 14.

### 11. Example Application to a Camera

The technology (the present technology) according to the present disclosure can be applied to various products. For example, the present technology may be embodied as an imaging device mounted in an imaging apparatus such as a camera.

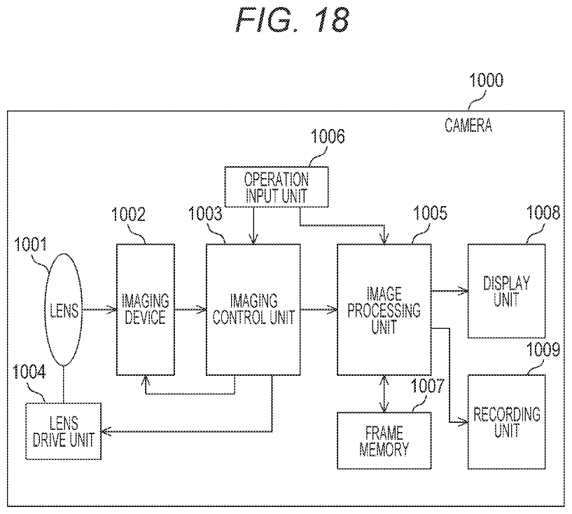

FIG. 18 is a block diagram showing a schematic example configuration of a camera that is an example of an imaging apparatus to which the present technology can be applied. A camera 1000 in the drawing includes a lens 1001, an imaging device 1002, an imaging control unit 1003, a lens drive unit 1004, an image processing unit 1005, an operation input unit 1006, a frame memory 1007, a display unit 1008, and a recording unit 1009.

The lens 1001 is the imaging lens of the camera 1000. The lens 1001 condenses light from the object, and causes the light to enter the imaging device 1002 described later, to form an image of the object.

The imaging device 1002 is a semiconductor element that images the light that has come from the object and been condensed by the lens 1001. The imaging device 1002 generates an analog image signal corresponding to the emitted light, converts the analog image signal into a digital image signal, and outputs the digital image signal.

The imaging control unit 1003 controls imaging in the imaging device 1002. The imaging control unit 1003 generates a control signal and outputs the control signal to the imaging device 1002, to control the imaging device 1002. The imaging control unit 1003 can also perform autofocusing in the camera 1000 on the basis of an image signal output from the imaging device 1002. Here, autofocusing is a system that detects the focal position of the lens 1001 and automatically adjusts the focal position. The autofocusing can be a method (image plane phase difference autofocusing) for detecting a focal position by detecting an image plane phase difference with a phase difference pixel disposed in the imaging device 1002. It is also possible to use a method (contrast autofocusing) for detecting a focal position that is the position at which the contrast of an image is the highest. The imaging control unit 1003 adjusts the position of the lens 1001 via the lens drive unit 1004 on the basis of the detected focal position, and performs autofocusing. Note that the imaging control unit 1003 can be formed with a digital signal processor (DSP) equipped with firmware, for example.

The lens drive unit 1004 drives the lens 1001, under the control of the imaging control unit 1003. The lens drive unit 1004 can drive the lens 1001 by changing the position of the lens 1001, using a built-in motor.

The image processing unit 1005 processes image signals generated by the imaging device 1002. This processing may be demosaicing for generating an image signal of an insufficient color among image signals corresponding to red, green, and blue for each pixel, noise reduction for removing noise in image signals, encoding of image signals, and the like, for example. The image processing unit 1005 can be formed with a microcomputer equipped with firmware, for example.

The operation input unit 1006 receives an operation input from the user of the camera 1000. As the operation input unit 1006, push buttons or a touch panel can be used, for example. An operation input received by the operation input unit 1006 is transmitted to the imaging control unit 1003 and the image processing unit 1005. After that, processing according to the operation input, such as imaging of the object, is started, for example.

The frame memory 1007 is a memory storing a frame that is the image signals of one screen. The frame memory 1007 is controlled by the image processing unit 1005, and holds a frame being subjected to image processing.

The display unit 1008 displays an image processed by the image processing unit 1005. For example, a liquid crystal panel can be used as the display unit 1008.

The recording unit 1009 records an image processed by the image processing unit 1005. For example, a memory card or a hard disk can be used as the recording unit 1009.

A camera to which the present disclosure can be applied has been described above. The present technology can be applied to the imaging device 1002 in the configuration described above. Specifically, the imaging device 1 described with reference to FIG. 1 can be applied to the imaging device 1002. By applying the imaging device 1 to the imaging device 1002, it is possible to reduce reflected light, and prevent degradation of the quality of an image generated by the camera 1000. Note that the image processing unit 1005 is an example of the processing circuit disclosed in the claims.

Note that, although a camera has been described as an example herein, the technology according to the present disclosure may also be applied to a distance sensor or the like, for example. Further, the present disclosure can also be applied to a semiconductor device in the form of a semiconductor module, in addition to electronic apparatuses such as a camera. Specifically, the technology according to the present disclosure can also be applied to an imaging module that is a semiconductor module in which the imaging device 1002 and the imaging control unit 1003 in FIG. 15 are contained in one package.

Lastly, the explanation of each embodiment described above is an example of the present disclosure, and the present disclosure is not limited to the embodiments described above. Accordingly, other than the respective embodiments described above, various changes may of course be made depending on the design and the like, without departing from the technical idea according to the present disclosure.

Further, the effects described in this specification are merely examples, and do not limit the effects of the technology. There may also be other effects.

Also, the drawings relating to the embodiments described above are schematic, and the dimensional ratios and the like of the respective components do not always match the actual ones. Further, it is needless to say that the dimensional relationships and ratios may differ between the drawings.

Note that the present technology may also be embodied in the configurations described below.

(1) An imaging device including:

an on-chip lens that condenses incident light;

a photoelectric conversion unit that is formed in a semiconductor substrate and performs photoelectric conversion on the condensed incident light; and

an absorption film that is disposed adjacent to the semiconductor substrate, has an opening of substantially the same size as a condensing size of the condensed incident light, and absorbs reflected light of the incident light.

(2) The imaging device according to (1), further including a reflective film that is disposed between the semiconductor substrate and the absorption film, and reflects the reflected light.

(3) The imaging device according to (2), in which the reflective film has an opening of a different size from the size of the opening of the absorption film.

(4) The imaging device according to (1) to (3), in which the absorption film has the opening formed in a shape with a smaller opening area on a side of the semiconductor substrate than an opening area on a side of the on-chip lens.

(5) The imaging device according to (4), in which the absorption film has the opening formed in a tapered shape.

(6) The imaging device according to (1) to (5), in which the absorption film is formed with a plurality of layers having different absorption coefficients.

(7) The imaging device according to (1) to (6), in which an absorbing material that absorbs the incident light is dispersed in the absorption film.

(8) The imaging device according to (1) to (7), in which the absorption film has a thickness substantially equal to a diameter of the opening.

(9) The imaging device according to (1) to (8), further including a second reflective film that is disposed on a different side of the semiconductor substrate from the side on which the absorption film is adjacent to the semiconductor substrate, and reflects the incident light having passed through the semiconductor substrate.

(10) The imaging device according to (1) to (9), further including a scattering portion that scatters the reflected light.

(11) The imaging device according to (10), in which the scattering portion is formed with irregularities formed in a surface of the semiconductor substrate adjacent to the opening of the absorption film.

(12) The imaging device according to (10), in which the scattering portion is disposed on a side of the semiconductor substrate different from the side on which the absorption film is adjacent to the semiconductor substrate, and reflects and scatters the incident light having passed through the semiconductor substrate.

(13) The imaging device according to (1) to (12), further including a plurality of pixels each including the on-chip lens, the photoelectric conversion unit, and the absorption film.

(14) The imaging device according to (13), in which the pixel further includes a color filter that transmits incident light of a predetermined wavelength in the incident light.

(15) The imaging device according to (14), in which the color filter transmits the incident light of a long wavelength.

(16) The imaging device according to (15), in which the color filter transmits red light.

(17) The imaging device according to (15), in which the color filter transmits infrared light.

(18) The imaging device according to (13) to (17), in which the absorption film is designed to have a position of the opening shifted in accordance with an incident angle of the incident light entering the pixel.

(19) The imaging device according to (13) to (17), in which the absorption film has a shape in which the opening is extended in accordance with an incident angle of the incident light entering the pixel.

(20) An imaging apparatus including:

an on-chip lens that condenses incident light;

a photoelectric conversion unit that is formed in a semiconductor substrate and performs photoelectric conversion on the condensed incident light;

an absorption film that is disposed adjacent to the semiconductor substrate, has an opening of substantially the same size as a condensing size of the condensed incident light, and absorbs reflected light of the incident light; and

a processing circuit that processes an image signal generated on the basis of the photoelectric conversion.

### REFERENCE SIGNS LIST

1 Imaging device
10 Pixel array unit
30 Column signal processing unit
100, 100a, 100b, 200 Pixel
101 Semiconductor substrate
109, 121 Scattering portion
110 Wiring region
112 Wiring layer
130 Separation region
120, 140 Reflective film
148, 148a, 148b, 149, 157 to 159 Opening
150 to 153 Absorption film
160 Protective film
170 Color filter
180 On-chip lens
1000 Camera
1002 Imaging device
1005 Image processing unit

1. An imaging device comprising:
an on-chip lens that condenses incident light;
a photoelectric conversion unit that is formed in a semiconductor substrate and performs photoelectric conversion on the condensed incident light; and
an absorption film that is disposed adjacent to the semiconductor substrate, has an opening of substantially the same size as a condensing size of the condensed incident light, and absorbs reflected light of the incident light.

2. The imaging device according to claim 1, further comprising a reflective film that is disposed between the semiconductor substrate and the absorption film, and reflects the reflected light.

3. The imaging device according to claim 2, wherein the reflective film has an opening of a different size from the size of the opening of the absorption film.

4. The imaging device according to claim 1, wherein the absorption film has the opening formed in a shape with a smaller opening area on a side of the semiconductor substrate than an opening area on a side of the on-chip lens.

5. The imaging device according to claim 4, wherein the absorption film has the opening formed in a tapered shape.

6. The imaging device according to claim 1, wherein the absorption film is formed with a plurality of layers having different absorption coefficients.

7. The imaging device according to claim 1, wherein an absorbing material that absorbs the incident light is dispersed in the absorption film.

8. The imaging device according to claim 1, wherein the absorption film has a thickness substantially equal to a diameter of the opening.

9. The imaging device according to claim 1, further comprising a second reflective film that is disposed on a different side of the semiconductor substrate from a side on which the absorption film is adjacent to the semiconductor substrate, and reflects the incident light having passed through the semiconductor substrate.

10. The imaging device according to claim 1, further comprising a scattering portion that scatters the reflected light.

11. The imaging device according to claim 10, wherein the scattering portion is formed with irregularities formed in a surface of the semiconductor substrate adjacent to the opening of the absorption film.

12. The imaging device according to claim 10, wherein the scattering portion is disposed on a side of the semiconductor substrate different from a side on which the absorption film is adjacent to the semiconductor substrate, and reflects and scatters the incident light having passed through the semiconductor substrate.

13. The imaging device according to claim 1, further comprising a plurality of pixels each including the on-chip lens, the photoelectric conversion unit, and the absorption film.

14. The imaging device according to claim 13, wherein the pixel further includes a color filter that transmits incident light of a predetermined wavelength in the incident light.

15. The imaging device according to claim 14, wherein the color filter transmits the incident light of a long wavelength.

16. The imaging device according to claim 15, wherein the color filter transmits red light.

17. The imaging device according to claim 15, wherein the color filter transmits infrared light.

18. The imaging device according to claim 13, wherein the absorption film is designed to have a position of the opening shifted in accordance with an incident angle of the incident light entering the pixel.

19. The imaging device according to claim 13, wherein the absorption film has a shape in which the opening is extended in accordance with an incident angle of the incident light entering the pixel.

20. An imaging apparatus comprising:
an on-chip lens that condenses incident light;
a photoelectric conversion unit that is formed in a semiconductor substrate and performs photoelectric conversion on the condensed incident light;
an absorption film that is disposed adjacent to the semiconductor substrate, has an opening of substantially the same size as a condensing size of the condensed incident light, and absorbs reflected light of the incident light; and
a processing circuit that processes an image signal generated on a basis of the photoelectric conversion.
